(19) United States
(12) Patent Application Publication
(10) Pub. No.: US 2001/0052394 A1
(43) Pub. Date: Dec. 20, 2001

(54) High density plasma processing apparatus

(76) Inventors: Soon-Bin Jung, Yongin-shi (KR); Bo-Shin Chung, Songnam-shi (KR)

Correspondence Address: Timothy J. Keefer, Wildman, Harrold, Allen & Dixon, 225 West Wacker Drive, Chicago, IL, 60606, US

(21) Appl. No.: 09/881,908

(22) Filed: Jun. 15, 2001

(30) Foreign Application Priority Data
Jun. 15, 2000 (KR) 2000-32869

(51) Int. Cl. H01L 21/3065

(52) U.S. Cl. 156/345; 118/723 I

(57) ABSTRACT

Disclosed is a high density plasma processing apparatus having a resonance antenna coil. The apparatus includes a processing chamber providing a hermetically sealed plasma generating space and having a planar surface on a top wall; a plurality of gas pipes that inject process gases into the processing chamber; a plurality of loop-shaped antennas installed on the planar surface and connected in parallel; a resonance antenna coil receiving a high frequency power and including the plurality of loop-shaped antennas and a plurality of variable capacitor that are connected in parallel with the plurality of loop-shaped antennas in order to maintain a resonance state therebetween; a means for heating the resonance antenna coil by way of using a heat exchange medium; and a means for fixing a substrate inside the processing chamber parallel with the planar surface of the top wall of the processing chamber.

This application claims the priority of Korean Patent Application No. 2000-32869, filed on Jun. 15, 2000, which is hereby incorporated by reference.

### BACKGROUND OF THE INVENTION

1. Field of the Invention

This invention relates to a semiconductor device manufacturing apparatus. More particularly, it relates to a high density plasma (HDP) processing apparatus which has resonance antenna coil to produce a uniform plasma density on and over a wafer (or a substrate).

2. Discussion of the Related Art

Nowadays since the semiconductor device is becoming integrated, it is difficult that the gaps between the metal lines having high aspect ratio are filled up by the insulating layer using a chemical vapor deposition (CVD) without any void. A major cause for the void is that an insulator deposition speed at the edges of the metal lines is faster than that in the sidewalls of the metal lines. Namely, the deposited insulator closes up an entrance of the gap before it fills up the gap.

To solve the above-mentioned problem, while forming the insulator by deposition, the plasma ions are impacted on the insulator near the edge of the metal lines using a radio frequency (RF) sputter etching process, thus deposition of the insulator is processed while etching the insulator at the edges of the metal lines.

Meanwhile, besides the chemical vapor deposition (CVD), the high density plasma (HDP) is recently used for manufacturing the semiconductor devices in order to improve the process efficiency in an etching or dry cleaning process. Especially by the inductively coupled plasma source, a low energy, i.e., a couple of electron volts (eV), can produce the high density plasma of 1×10¹¹˜2×10¹² ions/cm³ which is enough to strike ions against the process object. In the conventional semiconductor device manufacturing apparatus that uses the inductively coupled plasma, a helical antenna coil is arranged on an outer portion of a quartz dome that is a part of a vacuum chamber. That is, the helical antenna coil is wound around the exterior surface of the quartz dome. Then, an RF current (between about 100 KHz from about 100 MHz) flows through the antenna coil.

When operated in a resonance mode while the applied RF power is applied, the RF current circulating in the helical antenna coil generates an axial RF magnetic field in the processing chamber surrounded by the antenna coil. Once the plasma is lit (i.e., once the gas in the processing chamber becomes partially ionized by electron collisions), this RF magnetic field induces a circulating RF electron current in the gas in the enclosed chamber to maintain a high density plasma in the gas. This configuration may be considered as an RF transformer such that the antenna coil acts as the primary winding of the RF transformer and that the plasma itself acts as the secondary winding of the RF transformer.

However, such an inductively coupled plasma has a problem of lending to be non-uniform and annular shape above a substrate in the processing chamber. Namely, a hollow center effect, which shows lower plasma density over the center portion of the substrate, appears. This hollow center effect has a bad influence on ensuring a uniform processing on an entire surface of the substrate that is on an increasing tend in size. Furthermore, it is difficult to obtain uniform plasma clue to the fact that the windings constituting the antenna coil are series-connected with each other.

The antenna coil in the conventional apparatus is commonly made of a copper wire, and a cooler for the antenna coil is equipped in order to prevent an increasing temperature of the antenna coil, which is caused by the heat of the plasma during the high density plasma process. Although the copper is a thermal conductor, it is preferable that a better thermal conductive material than the copper is used as a winding of the antenna coil. Further, in the case the windings of the antenna coil are maintained at a lower temperature using the cooler for the antenna coil, a thermal shock in the windings can be caused by the temperature difference, and thus, the windings of the antenna coil can be fatigued and damaged finally. Because of the high temperature in the processing chamber and the lower temperature in the antenna coil, the atmosphere of the processing chamber is hardly changed into a stably high temperature in the beginning of the process.

### SUMMARY OF THE INVENTION

Accordingly, the present invention is directed to a plasma processing apparatus that substantially obviates one or more of the problems due to limitations and disadvantages of the related art.

To overcome the problems described above, the present invention provides a high density plasma processing apparatus that has a resonance antenna coil in order to produce uniform plasma on and over a substrate in the processing chamber.

Another object of the invention is to select a suitable material for windings of the antenna coil and to provide a high density plasma processing apparatus that can fix a suitable temperature for the antenna coil during a high density plasma process.

Additional features and advantages of the invention will be set forth in the description which follows, and in part will be apparent from the description, or may be learned by practice of the invention. The objectives and other advantages of the invention will be realized and attained by the structure particularly pointed out in the written description and claims thereof as well as the appended drawings.

To achieve these and other objects and in accordance with the purpose of the present invention, as embodied and broadly described a high density plasma processing apparatus includes a processing chamber providing a hermetically sealed plasma generating space and having a planar surface on a top wall; a plurality of gas pipes that inject process gases into the processing chanmber, a plurality of loop-shaped antennas installed on the planar surface of the top wall of the processing chamber and connected in parallel with each other; a resonance antenna coil receiving a high frequency power and including the plurality of loop-shaped antennas and a plurality of variable capacitor that are connected in parallel with the plurality of loop-shaped antennas in order to maintain a resonance state therebetween; a means for heating the resonance antenna coil by way of using a heat exchange medium; and a means for fixing a substrate inside the processing chamber parallel with the planar surface of the top wall of the processing chamber.

The plurality of loop-shaped antennas of the antenna coil are hollow tubes that have empty spaces thereinside. Further, the plurality of loop-shaped antennas of the antenna coil are made of silver-coated aluminum (Al).

The means for heating the resonance antenna coil circulates the heat exchange medium into the empty space of the plurality of loop-shaped antennas.

The high density plasma processing apparatus also includes a beater that supplies heat to the processing chanmber.

At least one gas pipe surrounds the means for fixing the substrate in a shape of a ring and the end of the this gas pipe bends toward and over the means for fixing the substrate so as to inject the process gases upward.

The preferred embodiment of the present invention further provides a high density plasma processing apparatus includes a processing chamber providing a hermetically sealed plasma generating space and having a planar surface on a top wall; a plurality of gas pipes that inject process gases into the processing chamber; a plasma electrode receiving a first high frequency power and being installed on the planar surface of the top wall of the processing chamber; a plurality of loop-shaped antennas installed on a surface of the top wall of the processing chamber except the planar surface and connected in parallel with each other; a resonance antenna coil receiving a second high frequency power and including the plurality of loop-shaped antennas and a plurality of variable capacitor that are connected in parallel with the plurality of loop-shaped antennas in order to maintain a resonance state therebetween; a means for heating the resonance antenna coil by way of using a heat exchange medium; and a means for fixing a substrate inside the processing chamber parallel with the planar surface of the top wall of the processing chamber.

According to above-mentioned apparatus, the plurality of loop-shaped antennas of the antenna coil have are hollow tubes that have empty spaces thereinside. Further, the plurality of loop-shaped antennas of the antenna coil are made of silver-coated aluminum (Al). The means for heating the resonance antenna coil circulates the heat exchange medium into the empty space of the plurality of loop-shaped antennas.

The first and second high frequency powers have a high frequency of greater than 1 MHz.

Moreover, at least one gas pipe surrounds the means for fixing the substrate in a shape of a ring and the end of the this gas pipe bends toward and over the means for fixing the substrate so as to inject the process gases upward.

It is to be understood that both the foregoing general description and the following detailed description are exemplary and explanatory and are intended to provide further explanation of the invention as claimed.

### BRIEF DESCRIPTION OF THE DRAWING

The accompanying drawings, which are included to provide a further understanding of the invention and are incorporated in and constitute a part of this specification, illustrate embodiments of the invention and together with the description serve to explain the principles of the invention.

In the drawings:

FIG. 1A is a schematic diagram illustrating a high density plasma processing apparatus according to a first embodiment of the present invention,

FIG. 1B is a schematic diagram illustrating a high density plasma processing apparatus according to a second embodiment of the present invention;

FIG. 1C is a schematic diagram illustrating a high density plasma processing apparatus according to a third embodiment of the present invention;

FIG. 2A is a schematic view showing the structure of a resonance antenna coil;

FIG. 2B is a view showing an equivalent circuit of FIG. 2A;

FIG. 3 is a graph showing distributions of a plasma density versus a position from the substrate center in a processing chamber, in order to indicate the effect of the present invention compared to a conventional art;

FIG. 4 is a 2-dimensional contour map for a thickness uniformity of a silicon oxide layer that is formed by a sputtering method on a silicon substrate using the first embodiment of the present invention; and

FIG. 5 is a 2-dimensional contour map for a thickness uniformity of a silicon oxide layer that is formed by a chemical vapor deposition method on a silicon substrate using the first embodiment of the present invention.

### DETAILED DESCRIPTION OF THE PREFERRED EMBODIMENTS

Reference will now be made in detail to embodiments of the present invention, which are illustrated in the accompanying drawings. Wherever possible, the same reference numbers will be used throughout the drawings to refer to die same or like parts.

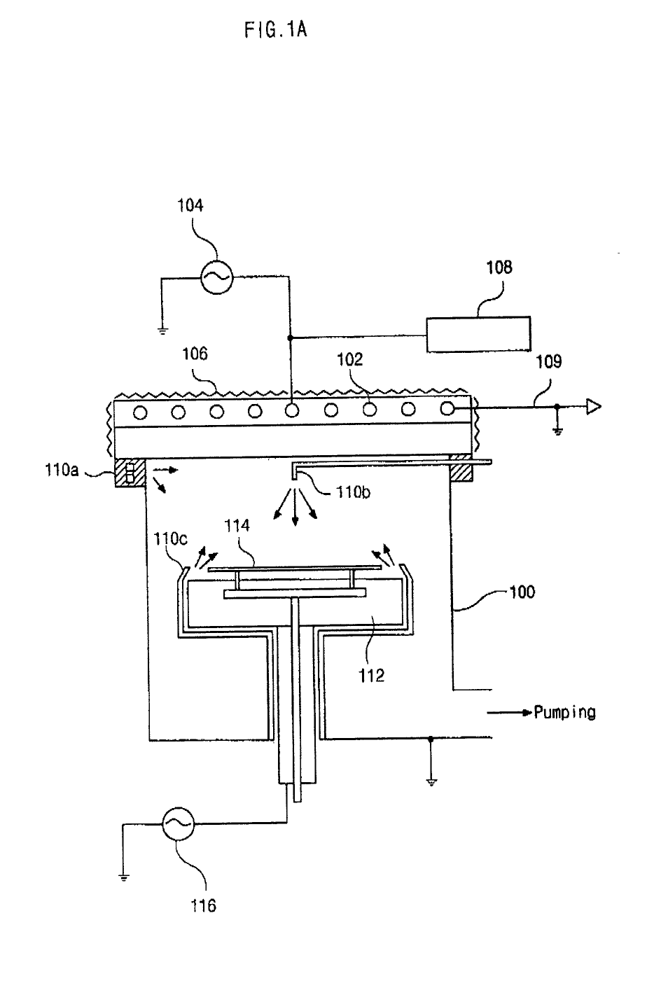

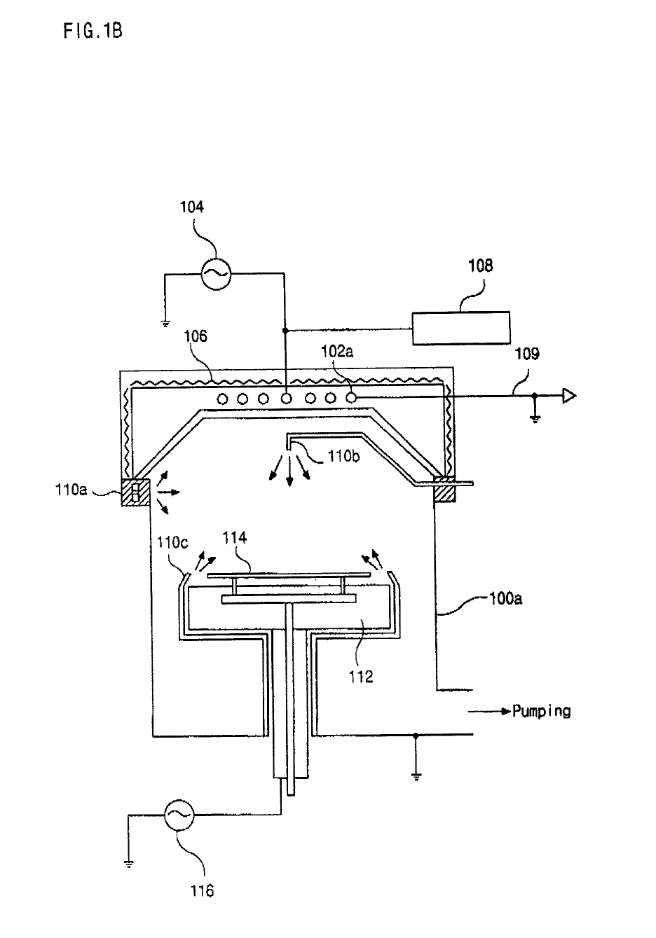

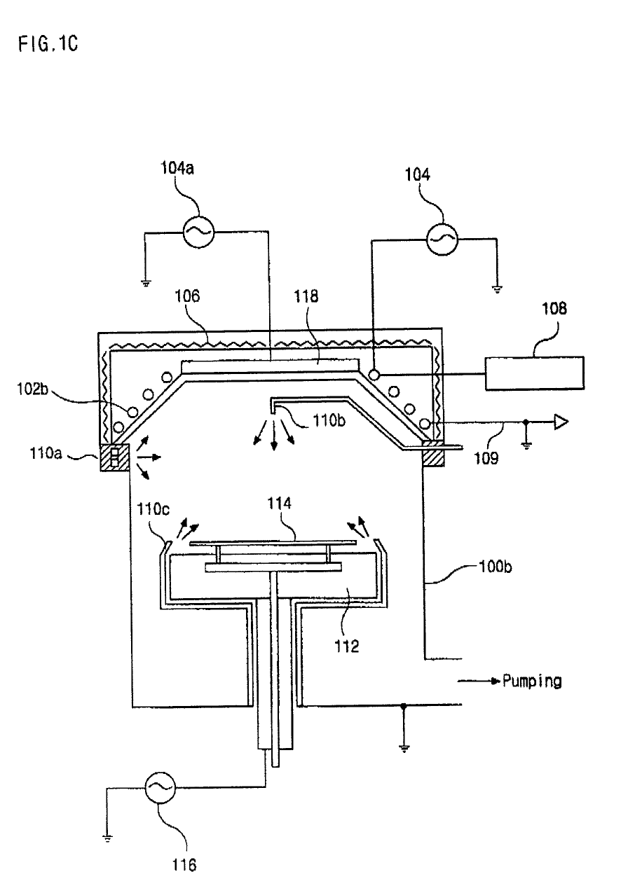

FIG. 1A is a schematic diagram illustrating a high density plasma processing apparatus according to a first embodiment of the present invention. As shown, the high density plasma processing apparatus comprises a processing chamber 100 having a sidewall, a top wall, and a bottom wall. The top wall of the processing chamber 100 has a planar upper surface, and a resonance antenna coil 102 is formed on the top wall of the processing chamber 100. The resonance antenna coil 102 is connected to a first RF power supply 104 that supplies a high frequency power having a frequency of 13.56 MHz to the resonance antenna coil 102. Windings (often referred to as antennas) of the resonance antenna coil 102 are hollow tubes. Also, the windings (or the antennas) of the resonance antenna coil 102 are made of aluminum (Al), and a surface of the windings is coated by silver (Ag).

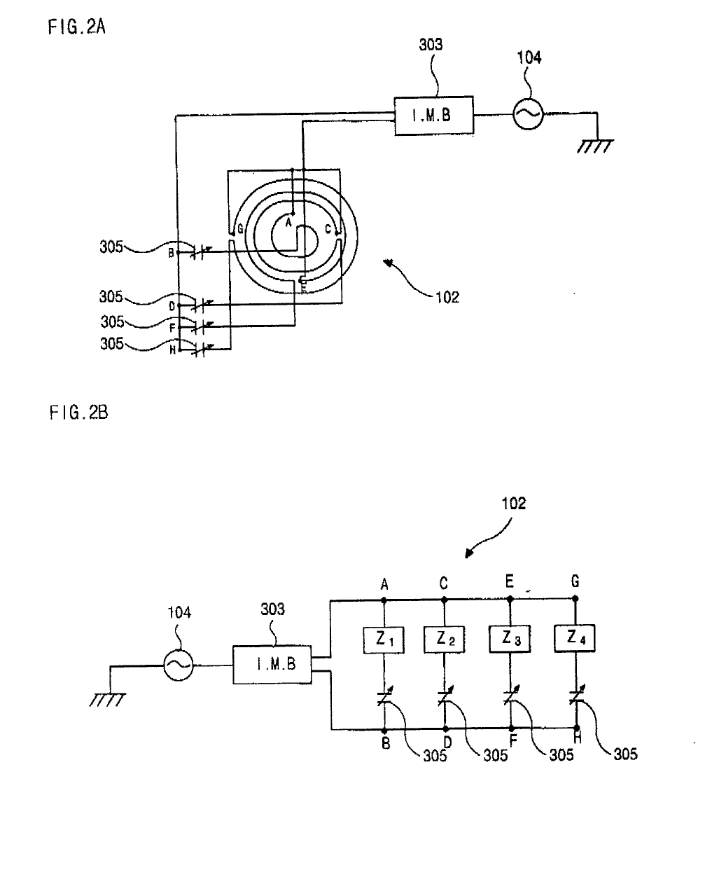

Now, referring to FIGS. 2A and 2B, the reference will be made in detail to the resonance antenna coil 102. FIG. 2A is a schematic view showing the structure of the resonance antenna coil 102, and FIG. 2B is a view showing an equivalent circuit of FIG. 2A.

Referring to FIG. 2A, the resonance antenna coil 102 comprises first, second, third and fourth antenna units. The first antenna unit includes a first antenna A-B with a series-connected variable load; the second antenna unit includes a second antenna C-D with a series-connected variable load; the third antenna unit includes a third antenna E-F with a series-connected variable load; and the fourth antenna unit includes a fourth antenna G-H with a series-connected variable load. Here in FIG. 2A, the variable loads are indicated as variable capacitors 305. Each antenna is shaped like a helix, and all antenna units are connected in parallel with each other. Although FIG. 2A shows only four antenna units, the number of the antenna units is changeable depending on the desirable property of the plasma processing apparatus. The winding (or the antenna) of each antenna unit is made of silver-coated aluminum (Al), and is a hollow tube as mentioned before.

Now, referring to FIG. 2B, the winding of each antenna unit is also represented by the impedance Z₁, Z₂, Z₃ or Z₄ that includes equivalent resistance and equivalent inductance. If the variable capacitors 305 are adjusted to make the imaginary portion of the equivalent impedance of each antenna unit be zero, the resonance state is maintained between the antenna units. Thus, the resonance state results in the equivalent intensity of the electric current circulating through each antenna unit, by way of adjusting the variable capacitors 305. Then, the electric current flowing the outer windings E-F and G-H of the antenna units can be increased due to the above-mentioned process.

The electric power is supplied from the high frequency power source 104 via an impedance matching box 303. The impedance matching box 303 functions as matching the impedances between the resonance antenna coil 102 and the high frequency power source 104. When using the resonance antenna coil 102, the variable capacitors 305 are adjusted to maintain the resonance state between the antennas and then the impedances are matched between the high frequency power source 104 and the resonance antenna coil 102. As a result, the electric power received from the high frequency power source 104 can be efficiently transmitted to the plasma in the processing chamber 100 of FIG. 1. Further, the plasma uniformity is improved in the processing chamber 100 (see FIG. 1).

Now, referring back to FIG. 1A, a heater 106, which applied heat to the atmosphere of the processing chamber 100, is fixated over the resonance antenna coil 102. This heater 106 can also surround the sidewalls of the processing chamber 100. The resonance antenna coil 102 is also connected to a antenna heating device 108 that lets a heat exchange medium flow into the insides of the hollow-tube antenna coil 102 in order to maintain the resonance antenna coil 102 at a temperature of 50 to 100 Celsius (° C.). The heat exchange medium from the antenna heating device 108 circulates through the hollow-tube antenna coil 102 and then is emitted through a exhaust pipe 109 to the outside.

In the first embodiment of the present invention, since the antenna coil 102 is installed on the planar surface of the top wall of the processing chamber 100, the hollow center effect mentioned before is prevented: in contrast to the conventional art that includes dome-shaped helical windings around a dome-shaped chamber ceiling (i.e., quartz dome). Further, since the antenna units are connected in parallel with each other and then turned to resonance, the better uniform plasma can be obtained.

Furthermore, not only are the windings of the antenna coil 102 formed of silver-coated aluminum hollow tube instead of copper, but also the antenna coil 102 are maintained at a fixed temperature using the antenna heating device 108 instead of the cooler. Therefore, owing to this configuration, the thermal shock does not occur in the windings of the antenna coil 102 during the plasma process after applying the high frequency power. Namely, the temperature difference is not big enough to cause the thermal shock because the antenna heating device 108 lets the heat exchange medium flow through the insides of the hollow-tube antennas.

Still, referring to FIG. 1A, first, second and third gas pipes 110a, 110b and 110c that supply and distribute process gases are equipped in the processing chamber 100 in order to obtain a uniform plasma density. The first gas pipe 110a is located in a top side portion of the processing chamber 100 and the second gas pipe 110b is located in the top central portion of the processing chamber 100. Especially, the third gas pipe 110c surrounds a susceptor 112 in a shape of a ring, and the end of the third gas pipe 110c bends toward and over the susceptor 112 as shown in FIG. 1A.

Since the process gases injected from the first and second gas pipes 110a and 110b are randomly distributed over a substrate 114, over the susceptor 112, and around the inner sidewalls of the processing chamber 100, the process efficiency of the process gases is lowered. Thus, the ring-shaped third gas pipe 110c is required around the susceptor 112 in order to increase the efficiency of the process gases that participate in a plasma process. Moreover, a lower RF power supply 106 is connected to the susceptor 112 and supplies a high frequency power having a frequency of 2 to 4 MHz. So a plasma dry cleaning process can be performed in inner surfaces of the processing chamber 100.

FIG. 1B is a schematic diagram illustrating a high density plasma processing apparatus according to a second embodiment of the present invention. Since the high density plasma processing apparatus depicted in FIG. 1B is similar to the first embodiment, some of the detailed explanations will be omitted.

Referring to FIG. 1B, a top wall of a processing chamber 100a is shaped like a trapezoid and has a planar upper surface. So the processing chamber 100a of the second embodiment has the top wall that is shaped into a truncated cone or a polyhedron. An antenna coil 102a is installed on the planar upper surface of the top wall. However, this antenna coil 102a can be installed on a slant of the top wall of the processing chamber 100a.

FIG. 1C is a schematic diagram illustrating a high density plasma processing apparatus according to a third embodiment of the present invention. As shown, a processing chamber 100b has a top wall that is shaped like a truncated cone or a polyhedron like as the second embodiment. However a plasma electrode 118, which applies a bias voltage with the substrate 114, is formed on a planar upper surface of the top wall instead of the antenna coil. Further, a resonance antenna coil 102b is installed on a slant of the top wall of the processing chamber 100b. A first RF power supply 104 is connected to the resonance antenna coil 102b, while a second RF power supply 104b is connected to the plasma electrode 118. Both the first and second RF power supplies 104 and 104b supply a high frequency power to the resonance antenna coil 102b and the plasma electrode 118, respectively.

According to the third embodiment of the present invention, the high density plasma processing apparatus produces both an inductively and a capacitively coupled plasma. Generally in the conventional art, in the case when both the inductively and the capacitivly coupled plasma are required in the process, the RF power supply for producing the inductively coupled plasma supplies a low frequency power, while the RF power supply for producing the capacitively coupled plasma supplies a high frequency power. However, as described in the third embodiment, both the first and second RF power supplies 104 and 104b supply a high frequency power having a frequency of a number of MHz.

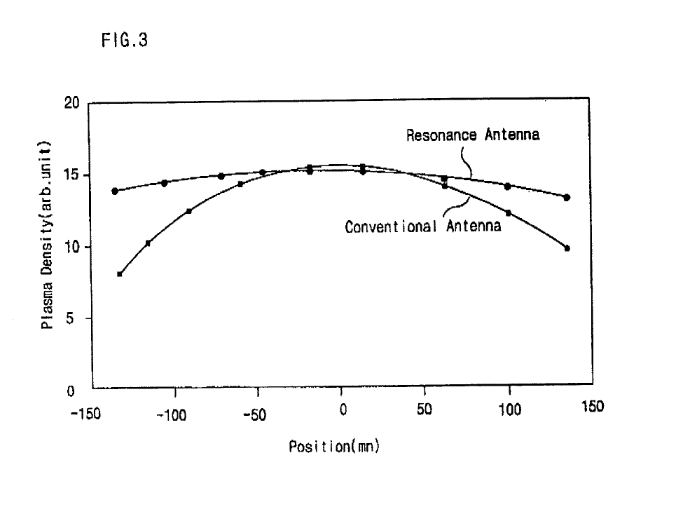

FIG. 3 is a graph showing distributions of a plasma density versus a position from the substrate center in a processing chamber, in order to indicate the effect of the present invention compared to a conventional art. As shown, the first embodiment that adopts the resonance antenna coil compares with the conventional art that has the conventional antenna coil. As a result of analysis, a uniformity of the plasma density is not swinging in the processing chamber even the position, according to the present invention.

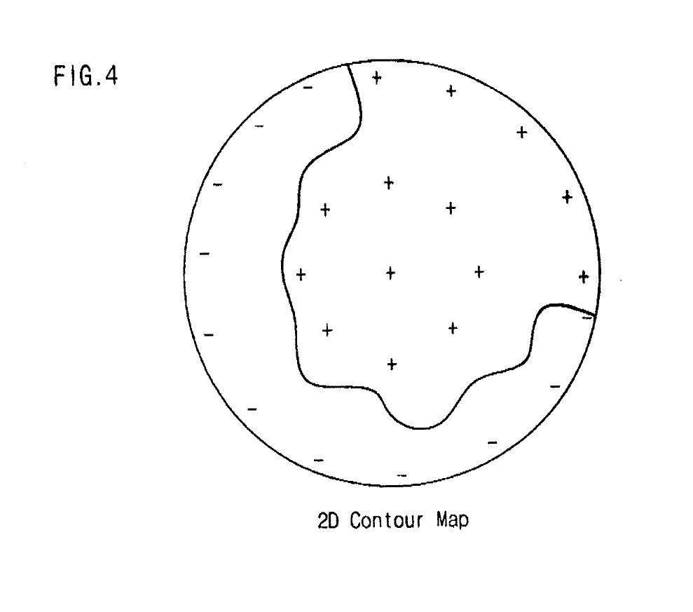

FIG. 4 is a 2-dimensional contour map for a thickness uniformity of a silicon oxide layer that is formed by a sputtering method on a silicon substrate using the first embodiment of the present invention. A diameter of the substrate is 200 mm, and the thickness of the sputtered layer is measured in 25 spots over the substrate. As a result of the measurement, a mean or average thickness of sputtered layer is 542 Angstroms (Å), and a standard deviation across the substrate is 8.9 Angstroms (Å). These mean or average thickness and standard deviation represent significantly improved uniformity in thickness of the sputtered layer, as compared to the prior art.

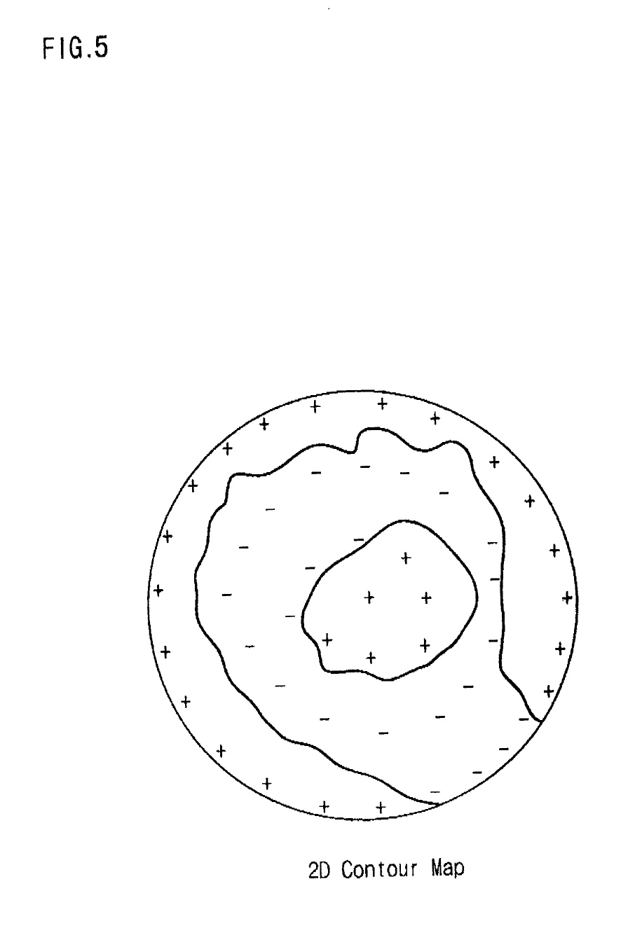

FIG. 5 is a 2-dimensional contour map for a thickness uniformity of a silicon oxide layer that is formed by a chemical vapor deposition method on a silicon substrate using the first embodiment of the present invention. A diameter of the substrate is 200 mm, and the thickness of the deposited layer is measured in 49 spots all over the substrate. As a result of the measurement, a mean or average thickness of deposited layer is 5530 Angstroms (Å), and a standard deviation across the substrate is 60.9 Angstroms (Å). These mean or average thickness and standard deviation represent significantly improved uniformity in thickness of the deposited layer, as compared to the prior art.

As described hereinbefore, a high processing uniformity on and over a surface of the large-sized substrate processed in the processing chamber is obtained during the semiconductor device manufacturing process using the high density plasma. Therefore, the high density plasma processing apparatus can be used in gap filling, chemical vapor deposition, sputtering, etc.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A high density plasma processing apparatus generating an inductively coupled plasma that is highly uniform, the apparatus comprising;
a processing chamber providing a hermetically sealed plasma generating space and having a planar surface on a top wall;
a plurality of gas pipes that inject process gases into the processing chamber;
a plurality of loop-shaped antennas installed on the planar surface of the top wall of the processing chamber and connected in parallel with each other;
a resonance antenna coil receiving a high frequency power and including the plurality of loop-shaped antennas and a plurality of variable capacitor that are connected in parallel with the plurality of loop-shaped antennas in order to maintain a resonance state therebetween;
a means for heating the resonance antenna coil by way of using a heat exchange medium; and
a means for fixing a substrate inside the processing chamber parallel with the planar surface of the top wall of the processing chamber.

2. The apparatus according to claim 1, wherein the plurality of loop-shaped antennas of the antenna coil are hollow tubes that have empty spaces thereinside.

3. The apparatus according to claim 2, wherein the plurality of loop-shaped antennas of the antenna coil are made of silver-coated aluminum (Al).

4. The apparatus according to claim 2, wherein the means for heating the resonance antenna coil circulates the heat exchange medium into the empty space of the plurality of loop-shaped antennas.

5. The apparatus according to claim 1, further comprising a heater that supplies heat to the processing chamber.

6. The apparatus according to claim 1, wherein at least one gas pipe surrounds the means for fixing the substrate in a shape of a ring and the end of the this gas pipe bends toward and over the means for fixing the substrate so as to inject the process gases upward.

7. A high density plasma processing apparatus generating a plasma that is highly uniform, the apparatus comprising:
processing chamber providing a hermetically sealed plasma generating space and having a planar surface on a top wall;
a plurality of gas pipes that inject process gases into the processing chamber;
a plasma electrode receiving a first high frequency power and being installed on the planar surface of the top wall of the processing chamber;
a plurality of loop-shaped antennas installed on a surface of the top wall of the processing chamber except the planar surface and connected in parallel with each other;
a resonance antenna coil receiving a second high frequency power and including the plurality of loop-shaped antennas and a plurality of variable capacitor that are connected in parallel with the plurality of loop-shaped antennas in order to maintain a resonance state therebetween,
a means for heating the resonance antenna coil by way of using a heat exchange medium; and
a means for fixing a substrate inside the processing chamber parallel with the planar surface of the top wall of the processing chamber.

8. The apparatus according to claim 7, wherein the plurality of loop-shaped antennas of the antenna coil are hollow tubes that have empty spaces thereinside.

9. The apparatus according to claim 8, wherein the plurality of loop-shaped antennas of the antenna coil are made of silver-coated aluminum (Al).

10. The apparatus according to claim 8, wherein the means for heating the resonance antenna coil circulates the heat exchange medium into the empty space of the plurality of loop-shaped antennas.

11. The apparatus according to claim 7, where the first and second high frequency powers have a high frequency of greater than 1 MHz.

12. The apparatus according to claim 7, wherein at least one gas pipe surrounds the means for fixing the substrate in a shape of a ring and the end of the this gas pipe bends toward and over the means for fixing the substrate so as to inject the process gases upward.
